(19) United States
(12) Patent Application Publication
(10) Pub. No.: US 2012/0091479 A1
(43) Pub. Date: Apr. 19, 2012

(54) ELECTROOPTIC DEVICE AND ELECTRONIC APPARATUS

(75) Inventors: Hiroyuki HARA, Chino-shi (JP); Tomoki YOKOTA, Chino-shi (JP)

(73) Assignee: Seiko Epson Corporation, Tokyo (JP)

(21) Appl. No.: 13/240,791

(22) Filed: Sep. 22, 2011

(30) Foreign Application Priority Data
Oct. 18, 2010 (JP) 2010-233936

(51) Int. Cl. H01L 27/15

(52) U.S. Cl. 257/88; 257/E27.12

(57) ABSTRACT

Pixel electrodes having reflectivity are arranged at a predetermined pitch in a matrix form on an effective display region on an opposed surface of an element substrate. A first conductive pattern which is formed by the same layer as the pixel electrodes is provided on an ineffective display region which is at an outer side with respect to the effective display region and at an inner side with respect to a sealing region when seen from the above. A second conductive pattern which is formed by the same layer as the pixel electrodes is provided on the sealing region. An area density of the second conductive pattern is smaller than an area density of the first conductive pattern when seen from the above.

Japanese Patent Application No. 2010-233936, filed Oct. 18, 2010 is incorporated by reference in its entirety herein.

### BACKGROUND

1. Technical Field

The present invention relates to an electrooptic device such as a reflection type liquid crystal panel, for example, and an electronic apparatus such as a projector which projects an image using the electrooptic device.

2. Related Art

For example, a reflection type liquid crystal panel is configured as follows. That is, an element substrate and a counter substrate which form a pair are bonded to each other with a sealing member while keeping a constant space therebetween and liquid crystal is sealed into the space. Pixel electrodes having reflectivity are arranged in a matrix form on a surface of the element substrate, which is opposed to the counter substrate. The pixel electrode is arranged for each pixel. On the other hand, a common electrode is provided on a surface of the counter substrate, which is opposed to the element substrate. The common electrode is provided so as to be opposed to all the pixel electrodes.

In such reflection type liquid crystal panel, in particular, in a liquid crystal panel having a display region of equal to or lower than 1-inch in a diagonal line, which is applied to a light bulb of a projector, for example, the following problem arises. That is, steps generated due to presence/absence of the pixel electrodes cause disturbance of liquid crystal alignment, optical scattering, and the like to deteriorate a contrast ratio in some case. In order to eliminate the steps, surfaces of the pixel electrodes are covered by an insulating layer and are flattened by a Chemical Mechanical Polishing (CMP) processing on the element substrate. Further, a technique to avoid generating differences in flatness between the inside and the outside of edges of an effective display portion by providing a conductive pattern on the outside of the effective display portion on which the pixel electrodes are arranged has been proposed (see, JP-A-2006-267937 (FIG. 4)). In the technique, the conductive pattern does not contribute to display but is formed by the same layer as the pixel electrodes. Further, the conductive pattern is provided so as to have substantially the same density as the pixel electrodes.

The reflection type liquid crystal panel has a configuration in which a silicon substrate having no light transmissivity is used as the element substrate in many cases. In this configuration, when a photocurable resin which cures with ultraviolet rays is used for the sealing member for bonding the element substrate and the counter substrate, only way for curing the sealing member is to irradiate the sealing member with light from only the counter substrate side. Therefore, there has arisen a problem in that the sealing member cannot be sufficiently cured or it takes much time to irradiate the sealing member with a sufficient amount of light for curing the sealing member.

It is considered that the problem is hardly caused when a substrate having a property of making at least ultraviolet rays transmit through the substrate, such as quartz, is used as the element substrate and light is also irradiated from the rear side of the element substrate (side opposite to the counter substrate), that is, light is irradiated from both surfaces of the substrate. However, as described above, it is required to pay attention to a point that the conductive pattern is formed on a portion on which the sealing member is to be formed on the element substrate. The pixel electrodes used in the reflection type liquid crystal panel are made of a layered metal having reflectivity, such as aluminum. Therefore, even if light is irradiated from the rear side of the element substrate, the light is reflected by the conductive pattern formed just under the sealing member and it is difficult to make the light irradiated from the rear side of the element substrate reach to the sealing member. Therefore, it has been considered that there arises a problem in that the sealing member cannot be sufficiently cured and so on.

### SUMMARY

An advantage of some aspects of the invention is to provide a technique of curing a sealing member with light irradiated from an observing side of a counter substrate and with light irradiated from a rear side of an element substrate while ensuring flatness of an opposed surface of an element substrate.

An electrooptic device according to an aspect of the invention includes a counter substrate and an element substrate which have light transmissivity and are arranged so as to be opposed to each other, an electrooptic element which is held between the counter substrate and the element substrate, a sealing member which bonds the counter substrate and the element substrate to each other, a plurality of pixel electrodes which are arranged on an effective pixel portion of the element substrate on which an image is displayed and have reflectivity, a first conductive pattern which is formed by the same layer as the plurality of pixel electrodes and is provided between the effective pixel portion and the sealing member when seen from the above, and a second conductive pattern which is formed by the same layer as the plurality of pixel electrodes and overlaps with the sealing member when seen from the above. In the electrooptic device, the second conductive pattern has an area density per unit area, which is smaller than an area density of the first conductive pattern, when seen from the above. The second conductive pattern overlapping with the sealing member has an area density smaller than that of the first conductive pattern which is provided between the effective pixel portion and the sealing member and flattens an opposed surface of the element substrate. Therefore, even if light is irradiated from the rear side of the element substrate, an amount of light reflected by the second conductive pattern is reduced. Accordingly, an amount of light passing through the second conductive pattern and reaching to the sealing member becomes larger as the amount of reflected light is reduced. Therefore, the sealing member can be cured with light irradiated from the rear side of the element substrate while ensuring flatness of the element substrate. It is to be noted that the light transmissivity referred herein is slightly different between the counter substrate and the element substrate. That is to say, the counter substrate is located at the observing side in general. Therefore, a property of making light components for curing the sealing member, for example, ultraviolet components and visible light transmit through the counter substrate is required for the counter substrate. On the other hand, it is sufficient that the element substrate has a property of making only light components for curing the sealing member transmit through the element substrate.

In the above configuration, it is preferable that the second conductive pattern include a plurality of wirings which extend in the direction perpendicular to an extension direction of the sealing member when seen from the above. With this configuration, since the second conductive pattern opens in a slit form on a portion where the sealing member is provided, light irradiated from the rear side of the element substrate can be made to reach to the sealing member efficiently.

It is preferable that the electrooptic device include a third conductive pattern which is connected to the second conductive pattern and is formed at an outer side of the sealing member. With this configuration, voltage is easily applied to the second conductive pattern from the outside through the third conductive pattern.

In this case, it is preferable that the voltage to be applied to the second conductive pattern be a common voltage to be applied to the common electrode formed on the surface of the counter substrate, the surface being opposed to the element substrate. With this, a direct-current component can be suppressed from being applied to the sealing member held between the common electrode and the second conductive pattern.

Further, it is preferable that a connecting portion which electrically connects the plurality of wirings be provided on the sealing region. If the connecting portion is not provided, fluctuation in voltage is caused to the sealing member due to wiring resistances. However, such fluctuation can be suppressed from occurring by providing the connecting portion.

Further, in the above configuration, it is preferable that the pixel electrodes be provided so as to correspond to intersections of a plurality of scan lines and a plurality of data lines when seen from the above, a pitch that the pixel electrodes are arranged be equal to an arrangement interval of the plurality of scan lines or the plurality of data lines, a pitch that the plurality of wirings are arranged be equal to the pitch that the pixel electrodes are arranged, and each width of the plurality of wirings be narrower than one side of the pixel electrodes when seen from the above. With this, the area density of the second conductive pattern can be easily made smaller than an area density of the first conductive pattern.

In the above configuration, it is preferable that when the electrooptic device has a lower conductive pattern which is positioned at a side opposite to the counter substrate with respect to the pixel electrodes, the first conductive pattern, and the second conductive pattern, the second conductive pattern overlap with the lower conductive pattern when seen from the above. With this configuration, the light irradiated from the rear side of the element substrate can be prevented from being shielded by the lower wiring pattern.

An electronic apparatus according to another aspect of the invention includes the electrooptic device. As the electronic apparatus, a projector which enlarges and projects a photo-modulated image which has been reflected by the reflection type liquid crystal panel may be exemplified.

### BRIEF DESCRIPTION OF THE DRAWINGS

The invention will be described with reference to the accompanying drawings, wherein like numbers reference like elements.

FIGS. 1A and 1B are views illustrating a configuration of a reflection type liquid crystal panel according to an embodiment of the invention.

FIG. 2 is a view illustrating a circuit configuration on the reflection type liquid crystal panel.

FIG. 3 is a view illustrating equivalent circuits of pixels on the reflection type liquid crystal panel.

FIG. 4 is a plan view illustrating a pixel configuration on the reflection type liquid crystal panel.

FIG. 5 is a plan view illustrating the pixel configuration on the reflection type liquid crystal panel.

FIG. 6 is a plan view illustrating the pixel configuration on the reflection type liquid crystal panel.

FIG. 7 is a partial cross-sectional view illustrating the pixel configuration on the reflection type liquid crystal panel.

FIG. 8 is a view for explaining each region of an element substrate on the reflection type liquid crystal panel.

FIGS. 9A and 9B are plan views illustrating a configuration of electrodes of the element substrate on each region.

FIG. 10 is a cross-sectional view illustrating an electrode laminate structure of the element substrate on a sealing region and the like.

FIG. 11 is a view illustrating a configuration of a projector to which the reflection type liquid crystal panel is applied.

### DESCRIPTION OF EXEMPLARY EMBODIMENTS

### Embodiments

Hereinafter, an embodiment of the invention is described. An electrooptic device according to the embodiment is a reflection type liquid crystal panel used as a light bulb of a projector, which will be described later. Note that a characteristic part of the liquid crystal panel according to the embodiment is a configuration of wirings on a portion on which a sealing member is overlapped. However, a relationship between the wirings and a conductive layer on an effective display portion is needed to be described. Therefore, a schematic configuration of the liquid crystal panel is described, at first. Further, in the following drawings, scales are made different in some case in order to make sizes of each layer, each member, each region, and the like be recognizable.

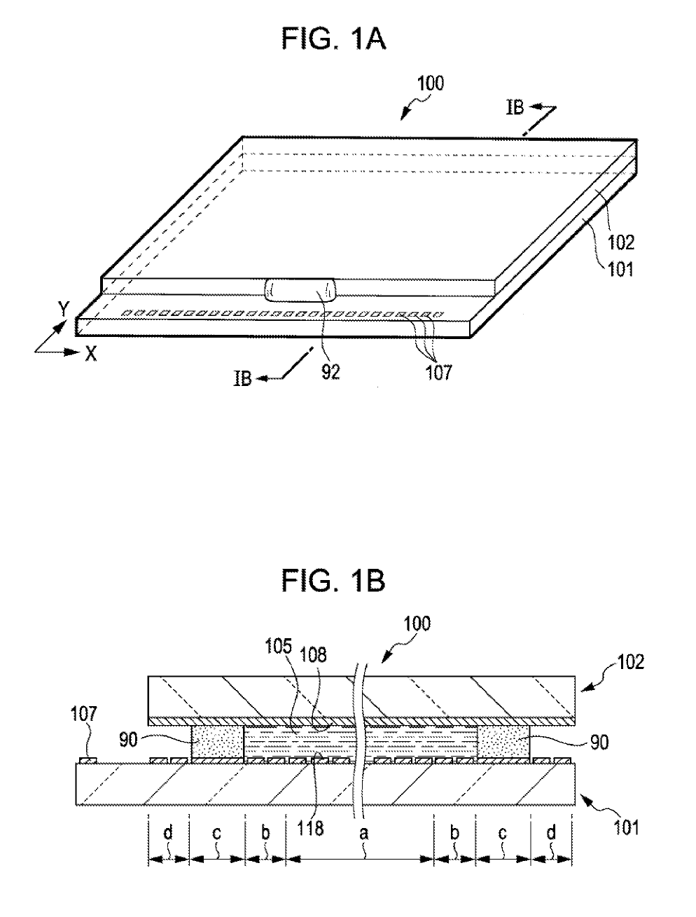

FIG. 1A is a perspective view illustrating a configuration of a liquid crystal panel 100 according to the embodiment and FIG. 1B is a cross-sectional view cut along a line IB-IB in FIG. 1A.

As illustrated in FIGS. 1A and 1B, the liquid crystal panel 100 is configured as follows. That is, an element substrate 101 on which pixel electrodes 118 are formed and a counter substrate 102 on which a common electrode 108 is formed are bonded to each other such that electrode formation surfaces thereof are opposed to each other while keeping a constant space therebetween with a sealing member 90 including a spacer (not illustrated) therebetween. For example, a vertical alignment (VA) type liquid crystal 105 is sealed into the space.

In the embodiment, a substrate having light transmissivity such as glass or quartz is used for the element substrate 101 and the counter substrate 102. In FIG. 1A, the element substrate 101 is longer than the counter substrate 102 in the Y direction. The element substrate 101 and the counter substrate 102 are bonded to each other in a state where sides thereof at a rear side (h side) are aligned to each other. Therefore, one side of the element substrate 101 at a front side (H side) projects with respect to the counter substrate 102. A plurality of terminals 107 are provided on the projected region along the X direction. It is to be noted that the plurality of terminals 107 are connected to a Flexible Printed Circuits (FPC) substrate and various types of signals and voltages, and video signals are supplied to the plurality of terminals 107 from an external higher-level apparatus.

The pixel electrodes 118 formed on the surface of the element substrate 101, which is opposed to the counter substrate 102, are formed by patterning a metal layer having reflectivity such as aluminum as will be described in detail later. The common electrode 108 provided on the surface of the counter substrate 102, which is opposed to the element substrate 101, is a conductive layer having transparency, such as Indium Tin Oxide (ITO).

It is to be noted that the sealing member 90 is formed in a frame form along inner edges of the counter substrate 102 when seen from the above as will be described later. However, a part of the sealing member 90 opens in order to pour into and seal the liquid crystal 105. Therefore, after the liquid crystal 105 has been poured into, the opening is sealed by a sealant 92. Further, although an alignment film is provided on each of the opposed surface of the element substrate 101 and the opposed surface of the counter substrate 102, the alignment films are not illustrated in FIG. 1B. Liquid crystal molecules are aligned along a normal line direction of the substrate surfaces with the alignment films in a state where a voltage is not applied.

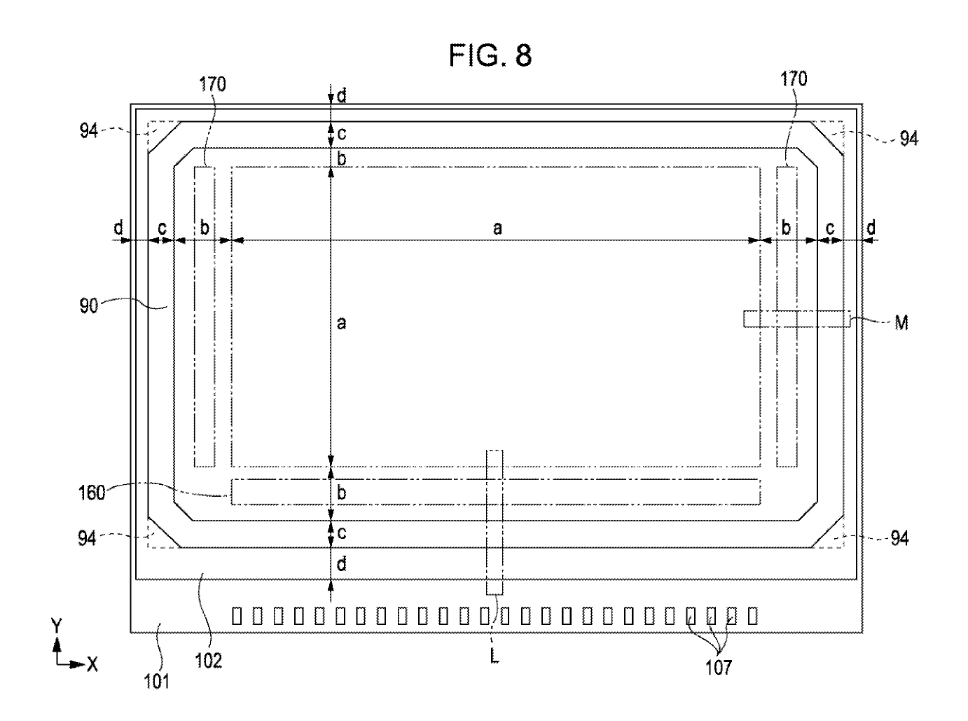

Regions “a”, “b”, “c”, “d” of the element substrate 101 as illustrated in FIG. 1B are described with reference to FIG. 8. FIG. 8 is a plan view illustrating the element substrate 101 when seen from the above in FIG. 1A, that is, from the counter substrate 102.

In FIG. 8, the region “a” corresponds to an effective display region (effective pixel portion) on which the pixel electrodes 118 contributing to display are arranged in a matrix form. The region “b” corresponds to an ineffective display region which is located at an outer side of the effective display region “a” and at an inner side of a region on which the sealing member 90 is formed. The region “c” is a sealing region overlapping with the region on which the sealing member 90 is formed. The region “d” is an outside region for sealing which is located at an outer side of the sealing region “c” and from which a portion on which the terminals 107 are arranged is not included. It is to be noted that in FIG. 8, the opening of the sealing member 90 and the sealant 92 are not illustrated.

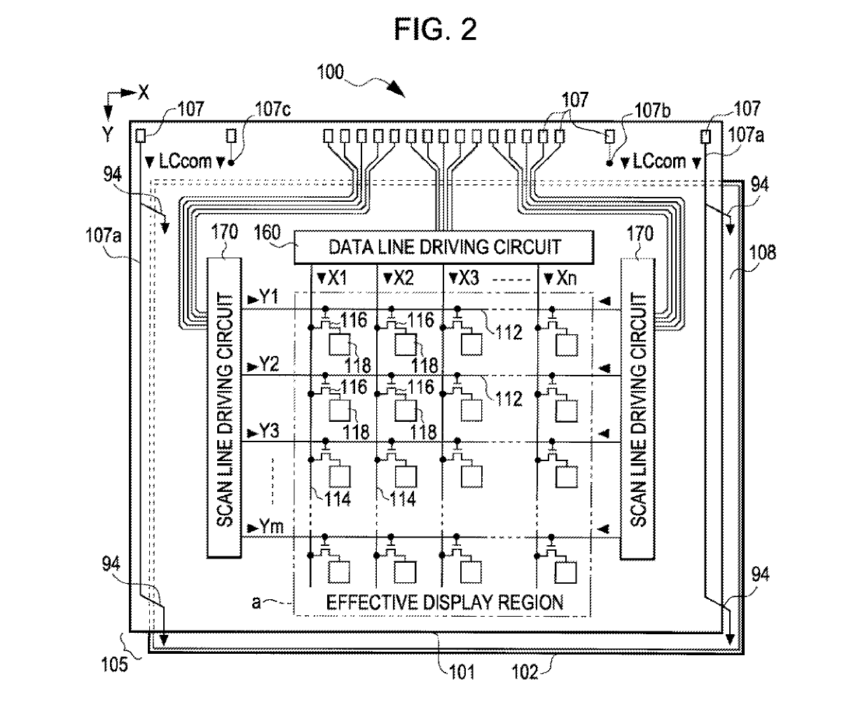

Next, an electric configuration of the liquid crystal panel 100 is described with reference to FIG. 2. FIG. 2 illustrates a positional relationship on the liquid crystal panel 100 when seen orthogonally from the lower side in FIG. 1A, that is, from the rear side of the element substrate 101, contrary to FIG. 8.

As described above, in the liquid crystal panel 100, the element substrate 101 and the counter substrate 102 are bonded to each other while keeping a constant space therebetween and the liquid crystal 105 is held within the space. A plurality of (m) rows of scan lines 112 are provided along the X direction and a plurality of (n) columns of data lines 114 are provided along the Y direction in FIG. 2 on the surface of the element substrate 101, which is opposed to the counter substrate 102. The scan lines 112 and the data lines 114 are kept to be electrically insulated from each other.

On the effective display region “a” of the element substrate 101, pairs of n-channel type TFTs 116 as an example of the switching element and the pixel electrodes 118 having reflectivity are provided so as to correspond to intersections of the (m) scan lines 112 and the (n) data lines 114. Gate electrodes of the TFTs 116 are connected to the scan lines 112, source electrodes thereof are connected to the data lines 114, and drain electrodes thereof are connected to the pixel electrodes 118. Therefore, in the embodiment, the pixel electrodes 118 are arranged on the effective display region “a” in an m×n matrix form.

It is to be noted that in FIG. 2, the opposed surface of the element substrate 101 when seen from the rear side corresponds to the back side of a paper plane. Therefore, although the scan lines 112, the data lines 114, the TFTs 116, and the pixel electrodes 118 should be indicated by dashed lines, these are indicated by solid lines in order to be easily viewed.

In the embodiment, in order to distinguish the data lines 114 from each other, the data lines 114 are referred to as 1, 2, 3, . . . , (n−1), and so on up to n^{th} column in the order from left in FIG. 2 in some case. In the same manner, in the embodiment, in order to distinguish the scan lines 112 from each other, the scan lines 112 are referred to as 1, 2, 3, . . . , (m−1), and so on up to m^{th} row in the order from above in FIG. 2 in some case.

A data line driving circuit 160 drives the data lines 114 of 1, 2, 3, . . . , and so on up to n^{th} column. As described in detail, the data line driving circuit 160 distributes video signals supplied through the terminals 107 to the data lines 114 of 1, 2, 3, . . . , and so on up to n^{th} column so as to make the distributed video signals be held by the data lines 114. To be more specific, the data line driving circuit 160 distributes the video signals by various control signals which have been also supplied through the terminals 107. Then, the data line driving circuit 160 supplies the video signals as data signals X1, X2, X3, . . . , and so on up to Xn. Further, the data line driving circuit 160 is provided on the ineffective display region “b”. To be more specific, the data line driving circuit 160 is provided on a region along one side on which the plurality of terminals 107 are provided, as illustrated in FIG. 8.

Two scan line driving circuits 170 drive the scan lines 112 of 1, 2, 3, . . . , and so on up to m^{th} row from both sides. As described in detail, the scan line driving circuits 170 generate scan signals Y1, Y2, Y3, . . . , and so on up to Ym by various control signals supplied through the terminals 107 so as to supply the scan signals Y1, Y2, Y3, . . . , and so on up to Ym from both sides of the scan lines 112 of 1, 2, 3, . . . , and so on up to m^{th} row. Further, the scan line driving circuits 170 are provided on the ineffective display region “b”. To be more specific, the scan line driving circuits 170 are provided on regions along two sides which are adjacent to the region on which the data line driving circuit 160 is formed, as illustrated in FIG. 8.

On the other hand, the common electrode 108 having transparency is provided on the entire surface of the counter substrate 102, which is opposed to the element substrate 101. A voltage LCcom is applied to the common electrode 108 through the terminals 107, wirings 107a, and conductive points 94 between the element substrate 101 and the counter substrate 102 in this order on the element substrate 101. It is to be noted that the conductive points 94 are located at four corners outside the frame of the sealing member 90 formed on inner circumferential edges of the substrate when seen from the above as illustrated in FIG. 8. The conductive points 94 are made to be conductive to the common electrode 108 with a conductive material such as silver paste.

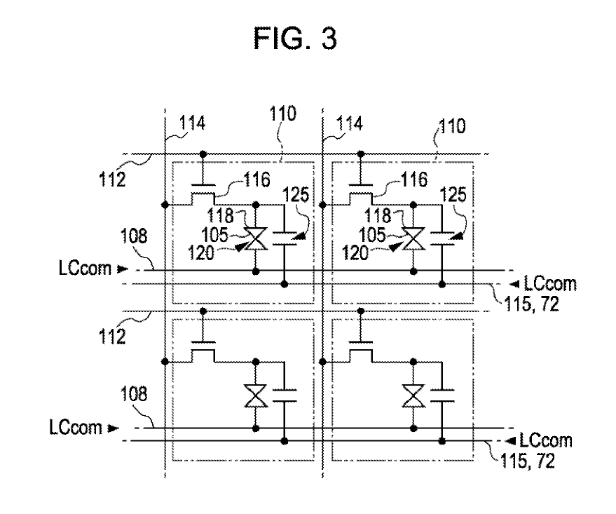

FIG. 3 is a view illustrating equivalent circuits of pixels 110 on the effective display region “a”. Liquid crystal elements 120 obtained by holding the liquid crystal 105 between the pixel electrodes 118 and the common electrode 108 are arranged so as to correspond to intersections of the scan lines 112 and the data lines 114.

It is to be noted that although not illustrated in FIG. 2, as illustrated in FIG. 3, auxiliary capacitances (accumulated capacitances) 125 are generally provided in parallel with the liquid crystal elements 120. One end of the auxiliary capacitance 125 is connected to the pixel electrode 118 and the other end thereof is commonly connected to the capacity line 115. In the embodiment, the voltage LCcom which is the same as that applied to the common electrode 108 is applied to the capacity lines 115.

In such configuration, if the scan line driving circuits 170 select one line of the scan lines and sets the selected scan line 112 to be an H level, the TFTs 116 of which gate electrodes are connected to the selected scan line are made to be an ON state and the pixel electrodes 118 are electrically connected to the data lines 114. Therefore, when the scan line 112 is at the H level, if the data line driving circuit 160 supplies a data signal having a voltage according to a gradation to the data lines 114, the data signal is applied to the pixel electrodes 118 through the TFTs 116 which have been made in the ON state. If the scan line 112 is at an L level, the TFTs 116 are made in an OFF state and the voltage applied to the pixel electrodes is held by capacitances of the liquid crystal elements 120 and the auxiliary capacitances 125.

The scan line driving circuits 170 select the scan lines 112 of first to m^{th} row in order and the data line driving circuit 160 supplies a data signal to pixels on one line located to correspond to the selected scan line 112 through the data lines 114. With this, the voltage in accordance with the gradation is applied to and held by all the liquid crystal elements 120. The operation is repeated for every one frame (one vertical scanning period).

On the liquid crystal elements 120, a molecular alignment state of the liquid crystal 105 is changed in accordance with an intensity of an electric field generated between the pixel electrodes 118 and the common electrode 108.

Light incident from an upper surface of the counter substrate 102 in FIG. 1A travels along a path of a polarizer (not illustrated), the counter substrate 102, the common electrode 108, and the liquid crystal 105 in this order. Then, the light is reflected by the pixel electrodes 118 and travels along a path in the direction opposite to the direction of the above path and is output. At this time, a ratio of an amount of output light with respect to an amount of light which is incident onto each liquid crystal element 120, that is, reflectance becomes larger as the voltage applied to and held by each liquid crystal element 120 is larger.

Thus, on the liquid crystal panel 100, the reflectance is changed for each of the liquid crystal elements 120. Therefore, each liquid crystal element 120 functions as a pixel as a minimum unit of an image to be displayed. Since the liquid crystal elements 120 are defined by the pixel electrodes 118 when seen from the above, a region on which the pixel electrodes 118 are arranged corresponds to the above effective display region “a”.

Subsequently, an element configuration of the effective display region “a” on the element substrate 101 is described.

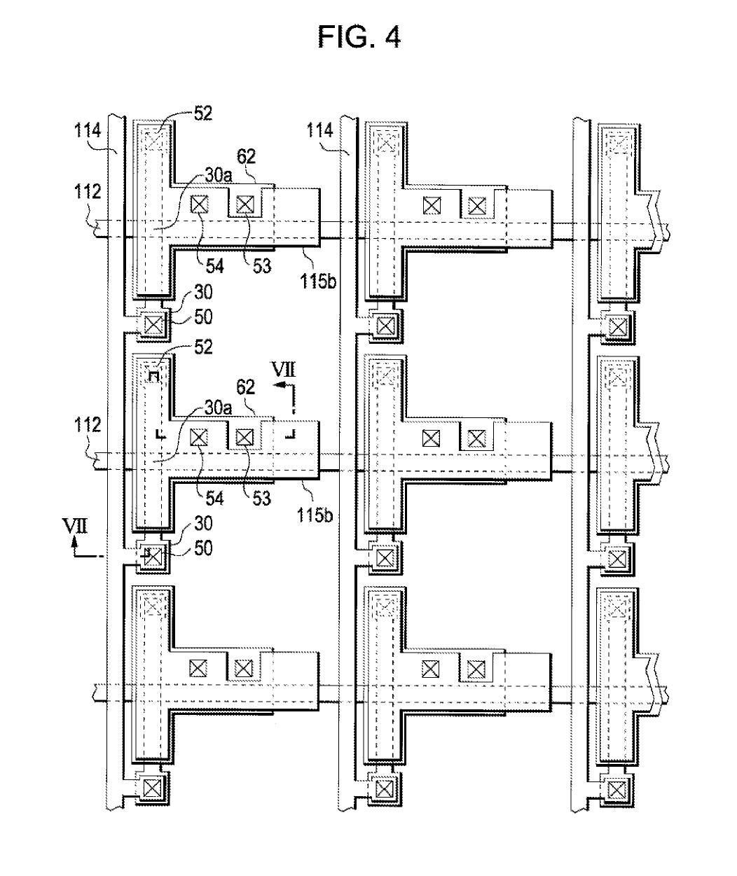

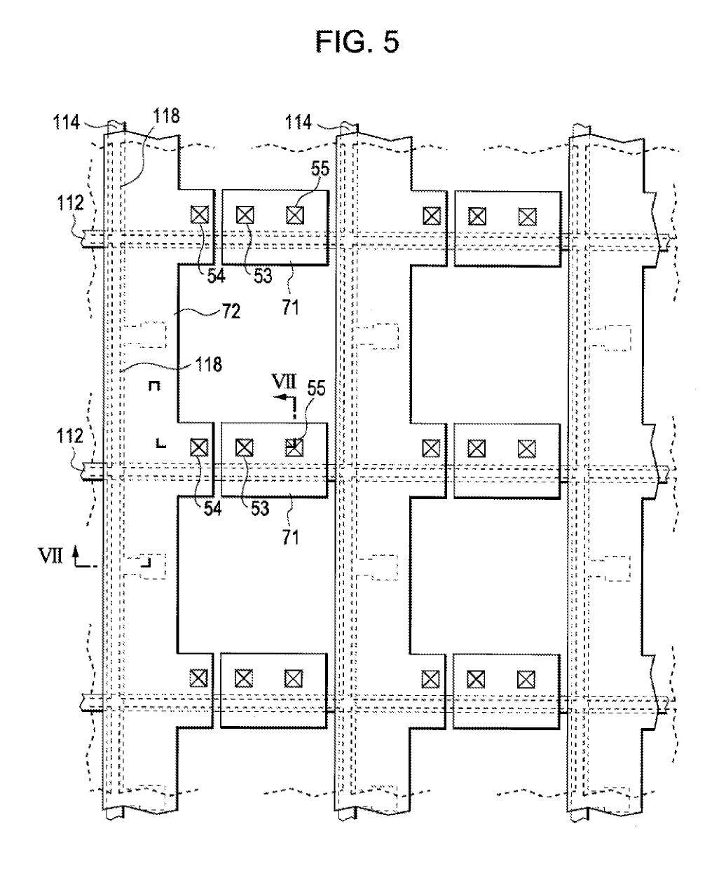

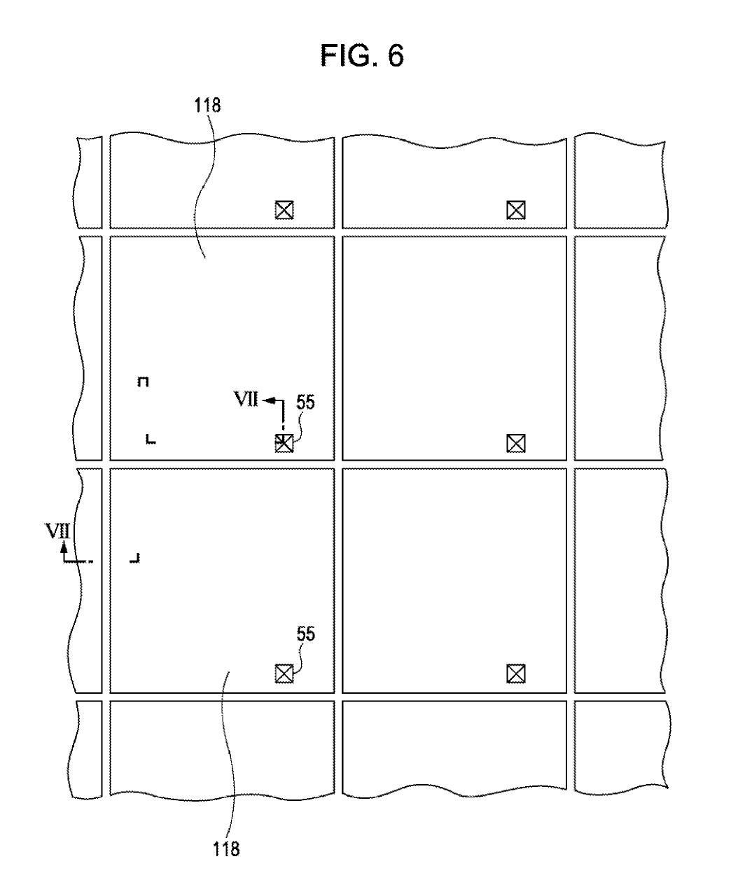

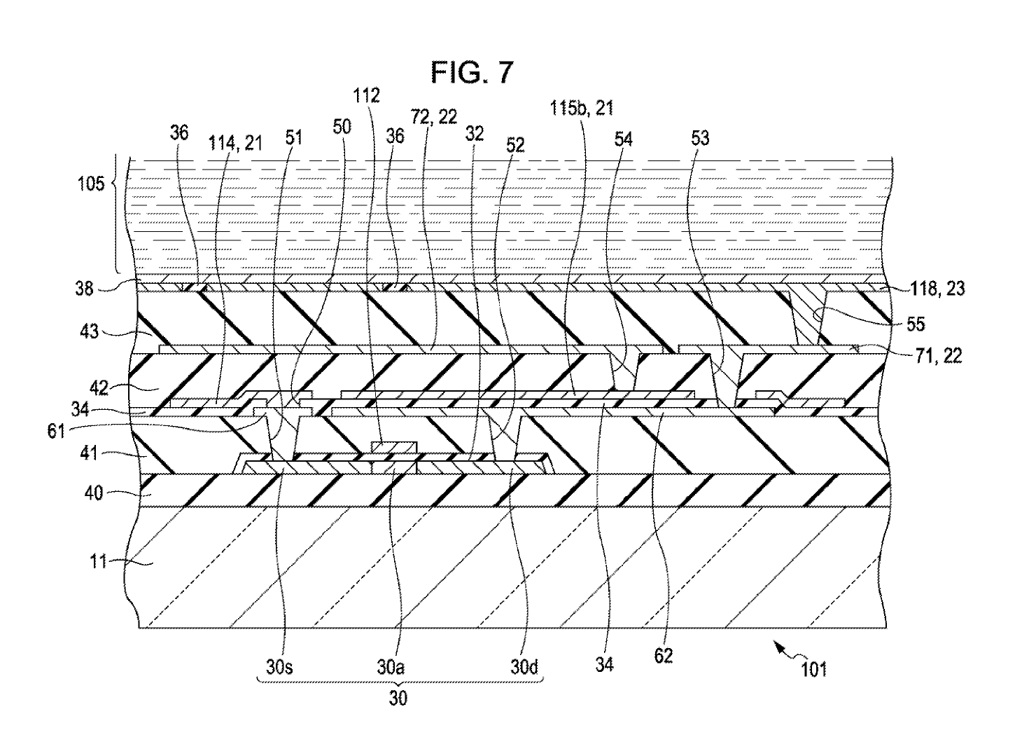

FIG. 4 through FIG. 6 are plan views illustrating a configuration of pixels. FIG. 7 is a partial cross-sectional view cut along a line VII-VII in FIG. 4 through FIG. 6. It is to be noted that in FIG. 4 through FIG. 6, in order to describe a configuration of the element substrate 101 when seen orthogonally from the opposed surface thereof, non-conductive members including an interlayer insulating film are not illustrated. FIG. 4 illustrates a configuration to a data line layer in the element configuration. FIG. 5 illustrates a shield electrode layer. FIG. 6 illustrates a pixel electrode layer.

At first, as illustrated in FIG. 7, a base insulating film 40 is provided on a substrate 11 as a base material of the element substrate 101. Further, semiconductor layers 30 made of polysilicon are provided on the base insulating film 40. A surface of each semiconductor layer 30 is covered with an insulating film 32 by thermal oxidation. A planar shape of each semiconductor layer 30 is formed into a rectangular shape such that lengthwise sides thereof extend in the longitudinal direction in FIG. 4, that is, the direction that each data line 114 extends, which is to be formed later.

The scan lines 112 are arranged so as to extend in the lateral direction in FIG. 4 and be substantially perpendicular to the semiconductor layers 30 formed into rectangular shapes at center portions of the semiconductor layers 30. As a result, as illustrated in FIG. 4 and FIG. 7, portions of the semiconductor layers 30, which overlap with the scan lines 112, correspond to channel regions 30a.

On the semiconductor layers 30, regions at a left side (lower side in FIG. 4) with respect to the channel regions 30a in FIG. 7 correspond to source regions 30s and regions at a right side (upper side in FIG. 4) with respect to the channel regions 30a in FIG. 7 correspond to drain regions 30d. Each source region 30s is connected to a relay electrode 61 through a contact hole 51 which penetrates through each of the insulating film 32 and a first interlayer insulating film 41. In the same manner, each drain region 30d is connected to a relay electrode 62 through a contact hole 52 which penetrates through each of the insulating film 32 and the first interlayer insulating film 41.

The relay electrodes 61, 62 are formed by patterning a conductive polysilicon film which is deposited on the first interlayer insulating film 41. A planar shape of each relay electrode 61 is substantially one size larger than each contact hole 51. Since the relay electrodes 61 hide behind branch portions of the data lines 114 located at an upper layer, the relay electrodes 61 are not illustrated in FIG. 4. On the other hand, each relay electrode 62 is formed into a substantially T shape including a portion extending in the longitudinal direction in FIG. 4 so as to cover each semiconductor layer 30 and a portion extending in the lateral direction so as to cover each scan line 112.

In FIG. 7, a dielectric layer 34 is deposited so as to cover the first interlayer insulating film 41 or the relay electrodes 61, 62. It is to be noted that the dielectric layer 34 is formed by a silicon oxide film, for example.

The data lines 114 and the capacitance electrodes 115b are formed by patterning a conductive two-layered film formed so as to cover the dielectric layer 34. As described in detail, the data lines 114 and the capacitance electrodes 115b are formed by patterning the two-layered film (data line layer 21) of a conductive polysilicon film which is deposited as a lower layer and an aluminum film which is deposited as an upper layer.

The data lines 114 are formed on the left side of the semiconductor layers 30 so as to extend in the longitudinal direction perpendicular to the scan lines 112 in FIG. 4. Further, the data lines 114 are formed so as to branch toward the source regions 30s (relay electrodes 61) on the semiconductor layers 30. The data lines 114 are connected to the relay electrodes 61 through the contact holes 50 which penetrate through the dielectric layer 34. Accordingly, the data lines 114 are connected to the source regions 30s through the relay electrodes 61.

Each capacitance electrode 115b is formed into a substantially T shape so as to cover each relay electrode 62. Note that each capacitance electrode 115b is formed into a partially cutout shape so as not to overlap with each contact hole 53 connecting to the drain region 30d.

In FIG. 7, a second interlayer insulating film 42 is formed so as to cover the data lines 114, the capacitance electrodes 115b or the dielectric layer 34. Relay electrodes 71 and shield electrodes 72 are formed by patterning a conductive two-layered film formed so as to cover the second interlayer insulating film 42. As described in detail, the relay electrodes 71 and the shield electrodes 72 are formed by patterning the two-layered film (shield electrode layer 22) of an aluminum film which is deposited as a lower layer and a titanium nitride film which is deposited as an upper layer.

The relay electrodes 71 are connected to the relay electrodes 62 through the contact holes 53 which penetrate through each of the second interlayer insulating film 42 and the dielectric layer 34. Further, the shield electrodes 72 are connected to the capacitance electrodes 115b through contact holes 54 which penetrate through the second interlayer insulating film 42.

A planar shape of each shield electrode 72 is formed as follows. That is, as illustrated in FIG. 5, each shield electrode 72 extends in the longitudinal direction so as to cover each data line 114 and the semiconductor layers 30 and projects in the right-lateral direction on the upper side of the scan lines 112 when seen from the above. The shield electrodes 72 are connected to the capacitance electrodes 115b through the contact holes 54 provided on the right-lateral projected portions.

On the other hand, a plnar shape of each relay electrode 71 is formed as follows. That is, as also illustrated in FIG. 5, each relay electrode 71 is formed in a rectangular form so as to be adjacent to each right-lateral projected portion of the shield electrode 72 at the upper side of each scan line 112. Each relay electrode 71 is formed as an island form for each pixel.

In FIG. 7, a third interlayer insulating film 43 is formed so as to cover the relay electrodes 71, the shield electrodes 72 or the second interlayer insulating film 42. The pixel electrodes 118 are formed by patterning an aluminum film (pixel electrode layer 23) formed so as to cover the third interlayer insulating film 43. The pixel electrodes 118 are connected to the relay electrodes 71 through the contact holes 55 which penetrate through the third interlayer insulating film 43. Accordingly, the pixel electrodes 118 are connected to the drain regions 30d through the relay electrodes 71 and the relay electrodes 62 in this order.

A planar shape of each pixel electrode 118 is formed into a substantially square shape as illustrated in FIG. 6. Further, each pixel electrode 118 is arranged so as to have such positional relationship that sides of each square are located at the inner side of the scan lines 112 and the data lines 114 as illustrated by dashed lines in FIG. 5.

A silicon oxide film is formed by a chemical vapor deposition using Tetra Ethyl Ortho Silicate (TEOS) as a material so as to cover the pixel electrodes 118 or the third interlayer insulating film 43. At this time, the silicon oxide film is also formed on the surfaces of the pixel electrodes 118. However, the silicon oxide film on the surfaces of the pixel electrodes 118 is scraped off by a CMP processing. As a result, the silicon oxide film 36 is left only on spaces between the adjacent pixel electrodes 118, as illustrated in FIG. 7. With this processing, the opposed surface of the element substrate 101 is flattened.

Further, an alignment film 38 made of an inorganic material is formed on the flattened surface. Although the alignment film 38 is not illustrated in detail in the drawings, the alignment film 38 is obtained by growing a plurality of fine columnar structures in a vaper phase in a state of being inclined in the same direction with oblique vapor deposition of silicon oxide, for example.

In the configuration, the shield electrodes 72 are drawn out to the sealing outside region “d” although not particularly illustrated in the drawings. Further, for example, the voltage LCcom which is the same as that applied to the common electrode 108 is commonly applied to the shield electrodes 72 through the terminal 107 and a connection point 107b in FIG. 2. Therefore, on the effective display region “a”, even if voltages of the data lines 114 are fluctuated through supply of the data signal, potential fluctuations due to capacitive coupling can be suppressed on the pixel electrodes 118, in particular, on the pixel electrodes 118 relating to the TFTs 116 in the OFF state.

Further, the light which is incident from the counter substrate 102 when seen from the above enters the spaces between the adjacent pixel electrodes 118 without being reflected by the pixel electrodes 118. However, since the semiconductor layers 30 are covered by the shield electrodes 72, the light entered from the opposed surface side does not deteriorate the off-leak characteristics of the TFTs 116.

Further, each auxiliary capacitance 125 is configured by a laminate structure in which the relay electrode 62, the dielectric layer 34, and the capacitance electrode 115b are laminated. Each capacitance electrode 115b is individually formed into an island form for each pixel. However, the capacitance electrodes 115b are connected to the shield electrodes 72 through the contact holes 54. Therefore, the voltage LCcom is commonly applied to the capacitance electrodes 115b over the pixels. Accordingly, the equivalent circuit is formed as illustrated in FIG. 3.

In the embodiment, on the effective display region “a”, the conductive layers including aluminum correspond to a total of three layers including the data line layer 21 constituting the data lines 114 and the capacitance electrodes 115b, the shield electrode layer 22 constituting the relay electrodes 71 and the shield electrodes 72, and the pixel electrode layer 23 constituting the pixel electrodes 118. The three layers are laminated in the above order.

Next, configurations of the conductive patternings of these three layeres on the ineffective display region “b”, the sealing region “c” and the outside sealing region “d” are described.

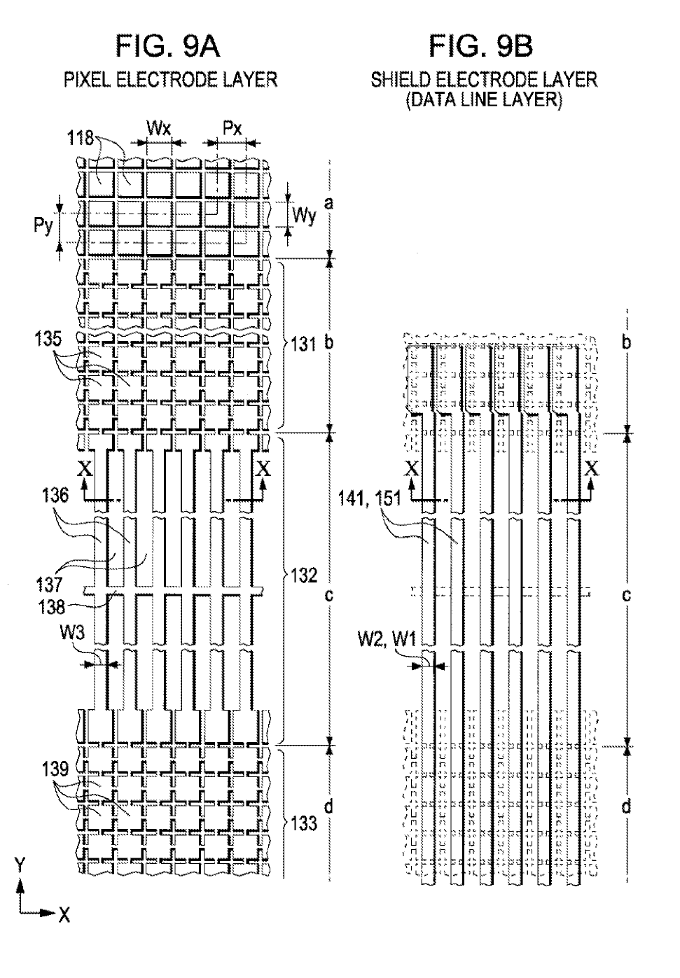

FIG. 9A is a plan view in which an L region in FIG. 8, that is, periphery of one side on which the terminals 107 are arranged over the effective display region “a”, the ineffective display region “b”, the sealing region “c”, and the outside sealing region “d” is partially enlarged. FIG. 9A illustrates a patterning shape of the pixel electrode layer 23 when the opposed surface of the element substrate 101 is seen from the above.

As illustrated in FIG. 9A and as described above, the pixel electrodes 118 are arranged in a matrix form on the effective display region “a”. The size of each pixel electrode 118 in the X direction is assumed to be Wx, and the size thereof in the Y direction is assumed to be Wy. It is to be noted that in this case, since each pixel electrode 118 is formed into a square shape, Wx is equal to Wy.

Further, when an arrangement pitch of the pixel electrodes 118 is defined to be a length between diagonal centers of the pixel electrodes 118, a pitch in the X direction is assumed to be Px, a pitch in the Y direction is assumed to be Py. In this case, the pitch Px is equal to an arrangement interval of the data lines 114 and the pitch Py is equal to an arrangement interval of the scan lines 112. It is to be noted that since the pixel electrodes 118 are formed into square shapes, Px is equal to Py.

In the embodiment, the pixel electrodes 118 are formed into the square shapes. However, when the liquid crystal panel is applied to applications other than a light bulb, such as an Electronic View Finder (EVE) of a digital still camera, for example, the pixel electrodes 118 are formed into rectangular shapes. In such case, the pixel electrodes 118 are formed into rectangular shapes because one dot is divided into three pixels of red (R), green (G) and blue (B), for example, and one dot is configured so as to have a square shape. Accordingly, as for the size of each pixel electrode 118, Wx is not always equal to Wy. Further, as for the pitch of the pixel electrodes 118, Px is not always equal to Py.

A first conductive pattern 131 formed by patterning the pixel electrode layer 23 is provided on the ineffective display region “b”. The first conductive pattern 131 is obtained by arranging electrodes 135 in a matrix form and connecting the electrodes 135 which are adjacent to each other in the longitudinal and lateral directions in the vicinity of centers of the sides so as to perform patterning. Each of the electrodes 135 has a size of Wx in the X direction and a size of Wy in the Y direction. That is to say, the electrodes 135 each having the same size as that of each pixel electrode 118 are arranged in the same manner as the arrangement of the pixel electrodes 118. Accordingly, the electrodes 135 are electrically connected to each other.

It is needless to say that the first conductive pattern 131 and the pixel electrodes 118 are not connected to each other.

A second conductive pattern 132 formed by patterning the pixel electrode layer 23 is provided on the sealing region “c”. The second conductive pattern 132 has a plurality of wirings 136. The plurality of wirings 136 are provided so as to be in parallel with each other with an interval of the pitch Px and extend in the direction (Y direction in FIG. 9A) perpendicular to the extension direction of the sealing member on the L region. Each of the plurality of wirings 136 is connected to the first conductive pattern 131 on the boundary between the ineffective display region “b” and the sealing region “c”.

Further, a line width W3 of each wiring 136 is narrower than the size Wx of each pixel electrode 118 and each electrode 135. Therefore, the second conductive pattern 132 has a plurality of silts 137 opened to have widths (Px-W3) larger than spaces (Px-Wx) between the pixel electrodes 118 and between the electrodes 135, respectively. In other words, an area density indicating a ratio of an occupied area of the second conductive pattern 132 per unit area on the sealing region “c” is smaller than an area density of the first conductive pattern 131 on the ineffective display region “b” when seen from the above. Therefore, an opening ratio of the second conductive pattern 132 is larger than an opening ratio of the first conductive pattern 131.

Further, the second conductive pattern 132 includes a wiring 138 which extends in the extension direction (X direction in FIG. 9A) of the sealing member and shorts the plurality of wirings 136.

It is to be noted that although a single wiring 138 is provided in an example of FIG. 9A, a plurality of wirings 138 may be provided.

A third conductive pattern 133 formed by patterning the pixel electrode layer 23 is provided on the outside sealing region “d”. The third conductive pattern 133 is obtained by arranging electrodes 139 each having the same size as that of each pixel electrode 118 in a matrix form in the same manner as the arrangement of the pixel electrodes 118 and connecting the electrodes 139 which are adjacent to each other in the longitudinal and lateral directions in the vicinity of centers on both sides so as to perform patterning. That is to say, the third conductive pattern 133 is a pattern in which a basic pattern which is the same as the first conductive pattern 131 is repeated.

It is to be noted that the third conductive pattern 133 is connected to the wirings 136 on the boundary of the sealing region “c”. On the other hand, the voltage LCcom is applied to the third conductive pattern through the terminal 107 and a connection point 107c (not illustrated in FIG. 9A) included in the outside sealing region “d” as illustrated in FIG. 2, for example.

Accordingly, the voltage LCcom is also applied to the second conductive pattern 132 and the first conductive pattern 131 through the third conductive pattern 133.

In the embodiment, wirings for connecting to various electrodes formed on the effective display region “a”, wirings for supplying a signal and the like to the data line driving circuit 160 and the scan line driving circuits 170 formed on the ineffective display region “b” are formed on the outside sealing region “d” by patterning the data line layer 21 and the shield electrode layer 22.

Next, wirings obtained by patterning the data line layer 21 and the shield electrode layer 22, in particular, in the vicinity of the sealing region “c” are described. It is to be noted that the data line layer 21 and the shield electrode layer 22 are located at the lower side with respect to the pixel electrode layer 23 (see, FIG. 7). Therefore, when the wirings obtained by patterning the data line layer 21 and the shield electrode layer 22 are generally referred, the wirings are called as a lower conductive pattern in some case.

FIG. 9B is a plan view in which the L region in FIG. 8 is enlarged as in FIG. 9A. FIG. 9B illustrates a shape obtained by patterning the shield electrode layer 22 when seen orthogonally from the opposed surface of the element substrate 101.

As illustrated in FIG. 9B, a plurality of wirings 141 formed by patterning the shield electrode layer 22 are provided on the sealing region “c” so as to overlap with the wirings 136 constituting the second conductive pattern 132 when seen from the above. As described in detail, the plurality of wirings 141 are provided to be in parallel with each other so as to extend in the direction perpendicular to the extension direction of the sealing member with the interval of the pitch Px. The wirings 141 are formed while centers of the wires are aligned such that a line width W2 corresponds to the line width W3 of each wiring 136 when a line width of each wiring 141 is assumed to be W2.

It is to be noted that in FIG. 9B, the electrodes 135, 139, and the like formed by patterning the pixel electrode layer 23 are indicated in dashed lines for indicating a positional relationship of the wirings 141 indicated in solid lines.

The wirings 141 obtained by patterning the shield electrode layer 22 are terminated in the middle on the ineffective display region “b” in FIG. 9B. This is because the wirings 141 are connected to a wiring layer and the like provided at the lower side through a contact hole, for example. In practice, the wirings 141 are patterned into various shapes depending on applications, properties and the like of the wirings on the ineffective display region “b”. In the same manner, although the wirings 141 have the same shape on the outside sealing region “d” as those on the sealing region “c”, the wirings 141 are patterned into various shapes depending on applications and the like of the wirings 141 on the outside sealing region “d”.

Further, the plurality of wirings 141 are used to be electrically independent on each other in many cases. Therefore, a wiring for shorting the wirings like the wiring 138 on the second conductive pattern 132 is not provided.

A plurality of wirings 151 formed by patterning the data line layer 21 are provided on the lower layer of the wirings 141 formed by patterning the shield electrode layer 22 on the sealing region “c”. The wirings 151 are provided so as to overlap with both of the wirings 136, 141 when seen from the above. As described in detail, the plurality of wirings 151 are also provided to be in parallel with each other so as to extend in the direction perpendicular to the extension direction of the sealing member with the interval of the pitch Px. Further, the wirings 151 are also formed while centers of the wires are aligned such that a line width W1 corresponds to the line width W2 of each wiring 141 when a line width of each wiring 151 is assumed to be W1.

Therefore, the wirings 151 on the sealing region “c” are illustrated in parentheses in FIG. 9B because the shapes of wirings 151 cannot be distinguished from those of the wirings 141 when seen from the above.

The point that the wirings 151 are patterned into various shapes depending on applications and the like on the ineffective display region “b” and the outside sealing region “d” is the same as in the wirings 141.

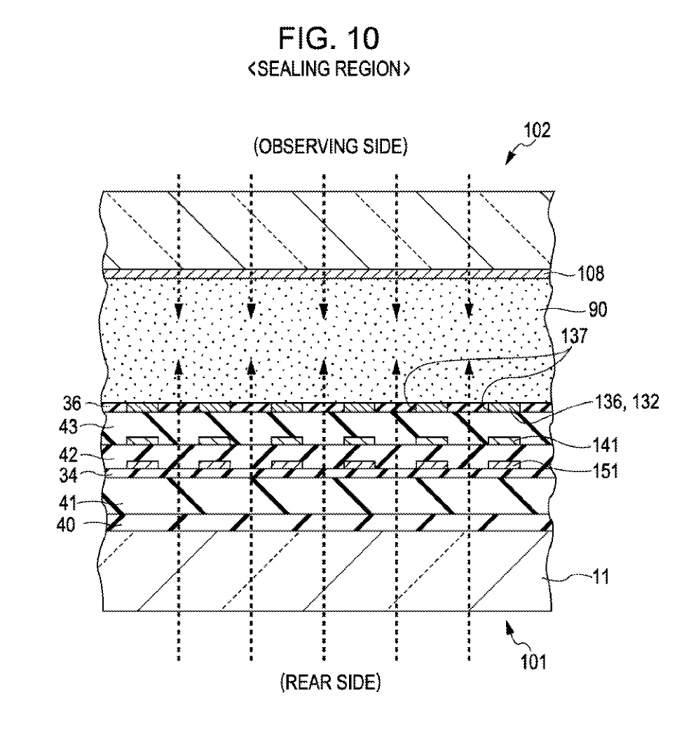

FIG. 10 is a partial cross-sectional view cut along a line X-X in FIG. 9A and FIG. 9B. FIGS. 9A and 9B illustrate only the element substrate 101, but FIG. 10 illustrates the element substrate 101 and the counter substrate 102 for convenience.

As illustrated in FIG. 10, on the element substrate 101, the second conductive pattern 132 (wirings 136) formed on the sealing region are provided on an upper layer with respect to the wirings 141 and the wirings 151 on the lower conductive pattern. To be more specific, the second conductive pattern 132 (wirings 136) are provided at positions so as to overlap with the wirings 141 and the wirings 151. Therefore, when the element substrate 101 and the counter substrate 102 are bonded to each other, light irradiated from the rear side of the element substrate 101 reaches to the sealing member 90 through the slits 137.

Further, on portions which do not constitute the first conductive pattern 131, the second conductive pattern 132 and the third conductive pattern 133, the silicon oxide film 36 is embedded with the CMP processing in the same manner as in the case of the effective display region “a”. Note that the portions which do not constitute the first conductive pattern 131, the second conductive pattern 132 and the third conductive pattern 133 correspond to portions on which the pixel electrode layer 23 is not present on the ineffective display region “b”, the sealing region “c”, and the outside sealing region “d”. Therefore, not only the effective display region “a” but also peripheral regions of the effective display region “a” on the opposed surface (upper surface) of the element substrate 101 are flattened.

Therefore, according to the embodiment, the sealing member can be cured with light irradiated from the observing side of the counter substrate 102, in addition with light irradiated from the rear side of the element substrate 101 while ensuring flatness of the element substrate 101.

In the embodiment, a reason why the third conductive pattern 133 is formed on the outside sealing region “d” and the CMP processing is performed on the third conductive pattern 133 is as follows. That is to say, the element substrate 101 is individually cut out one by one by dicing after a plurality of the element substrates 101 are formed on a wafer. The CMP processing is performed at a stage of the wafer. Therefore, when the third conductive pattern 133 is also left on the boundaries between adjacent element substrates, flatness can be ensured more desirably in comparison with a case where the third conductive pattern 133 is not left on the boundaries.

Further, the sealing member 90 on the sealing region “c” is configured to be held between the common electrode 108 and the second conductive pattern 132 (wirings 136). The voltage LCcom which is the same as that applied to the common electrode 108 is applied to the second conductive pattern 132 through the terminal 107, the connection point 107c and the third conductive pattern 133 in this order. Therefore, the voltage applied to the sealing member 90 is zero. Therefore, even when a component deteriorating a moisture-retaining property due to application of direct current is included in the sealing member 90, such deterioration can be prevented.

In addition, the second conductive pattern 132 is obtained by arranging the plurality of wirings 136 so as to extend in the direction perpendicular to the extension direction of the sealing member and be in parallel with each other in the extension direction of the sealing member. These wirings 136 are shorted by the wiring 138. Therefore, on the sealing region “c”, application of different voltages to the wirings 136 due to wiring resistances is suppressed from occurring.

Further, the voltage LCcom is also applied to the first conductive pattern 131 through the third conductive pattern 133 and the second conductive pattern 132. Therefore, a direct-current component is not applied to the liquid crystal 105 on the ineffective display region “b”.

The sealing region “c” has been described by taking the L region in the vicinity of one side on which the terminals 107 are arranged as an example. However, an M region on which the scan line driving circuit 170 is provided has a configuration obtained by rotating FIG. 9A by 90 degrees in the counterclockwise direction. On the M region, the extension direction of the sealing member corresponds to the Y direction. Therefore, on the second conductive pattern 132, the extension direction of the wirings 136 corresponds to the X direction and the extension direction of the wiring 138 which shorts the wirings 136 corresponds to the Y direction. Further, the arrangement pitch of the wirings 136 is equal to the arrangement pitch of the scan lines 112.

Further, in the liquid crystal panel 100 according to the embodiment, the line width W3 of each wiring 136 formed by patterning the pixel electrode layer 23 on the sealing region “c”, the line width W2 of each wiring 141 formed by patterning the shield electrode layer 22, and the line width W1 of each wiring 151 formed by patterning the data line layer 21 are set to satisfy a relationship of W3=W2=W1. However, it is sufficient that the positional relationship in which the wirings 136, the wirings 141, and the wirings 151 are overlapped with each other when seen orthogonally from the opposed surface and the lower conductive pattern does not project from the wirings 136 is realized. A relationship of W3≧W2≧W1 may be applicable as long as the positional relationship is satisfied.

The pattern obtained by patterning the data line layer 21 and the shield electrode layer 22 is used for the lower conductive pattern in the embodiment. However, a polysilicon film constituting the scan lines 112 and a polysilicon film constituting the relay electrodes 61, 62 may be used.

Further, the invention is not limited to the liquid crystal panel and may be a display panel which holds an electrooptic substance between two substrates on a display region surrounded by the sealing member. For example, the invention can be applied to an organic EL panel, an inorganic EL panel, an electrophoretic device, and the like. Even if these configurations are employed, the substantially same action effects as those obtained in the above embodiment and modifications can be obtained.

### Electronic Apparatus

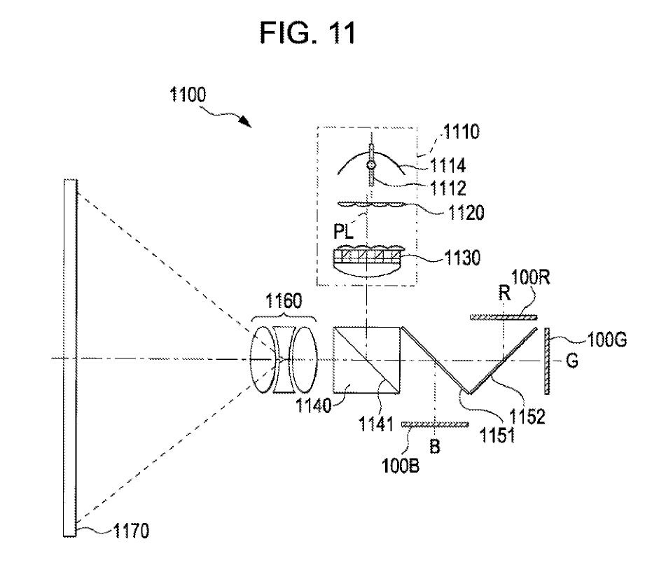

Next, an electronic apparatus to which the reflection type liquid crystal panel 100 according to the above embodiment is applied will be described. FIG. 11 is a plan view illustrating a configuration of a projector 1100 using the liquid crystal panels 100 as light bulbs.

As illustrated in FIG. 11, the projector 1100 is a three-plate type projector in which the reflection type liquid crystal panels 100 according to the embodiment correspond to each color of red (R), green (G), and blue (B). A polarization illumination device 1110 is arranged along a system optical axis PL in the projector 1100. In the polarization illumination device 1110, output light from a lamp 1112 is reflected by a reflector 1114 so as to become substantially a parallel light beam. Then, the output light beam is incident onto a first integrator lens 1120. The output light from the lamp 1112 is divided into a plurality of intermediate light beams by the first integrator lens 1120. The divided intermediate light beams are converted to one type of polarized light beams (s polarized light beams) of which polarization direction is substantially aligned by a polarization conversion element 1130 having a second integrator lens at a light incident side. Then, the polarized light beams are output from the polarization illumination device 1110.

The s polarized light beams output from the polarization illumination device 1110 are reflected by an s polarized light beam reflection surface 1141 of a polarizing beam splitter 1140. A light beam of blue light (B) among the reflected light beams is reflected by a blue light reflection layer of a dichroic mirror 1151 and modulated by the liquid crystal panel 100B. Further, a light beam of red light (R) among light beams transmitted through the blue light reflection layer of the dichroic mirror 1151 is reflected by a red light reflection layer of a dichroic mirror 1152 and modulated by the liquid crystal panel 100R. Further, a light beam of green light (G) among light beams transmitted through the blue light reflection layer of the dichroic mirror 1151 transmits through the red light reflection layer of the dichroic mirror 1152 and is modulated by the liquid crystal panel 100G.

Note that the liquid crystal panels 100R, 100G, and 100B have the same configurations as that of the liquid crystal panel 100 in the above embodiment and are driven by supplied data signals corresponding to each color of R, G, B. That is to say, on the projector 1100, three liquid crystal panels 100 are provided so as to correspond to colors of R, G, B and are driven in accordance with the video signals corresponding to the colors of R, G, B, respectively.

The red, green, and blue lights modulated by the liquid crystal panels 100R, 100G, 100B, respectively, are sequentially synthesized by the dichroic mirrors 1152, 1151, and the polarizing beam splitter 1140. Then, the red, green, and blue lights are projected onto a screen 1170 by a projection optical system 1160. It is to be noted that light beams corresponding to primary colors of R, G, and B are incident onto the liquid crystal panels 100R, 100B and 100G, respectively, by the dichroic mirrors 1151, 1152. Therefore, color filters are not required to be provided.

It is to be noted that the above EVF, a rear projection-type television, a head-mounted display, and the like are exemplified as the electronic apparatus in addition to the projector which has been described with reference to FIG. 11.

What is claimed is:

1. An electrooptic device comprising:
an element substrate which has light transmissivity;
a counter substrate which has light transmissivity and is arranged so as to be opposed to the element substrate;
an electrooptic element which is held between the counter substrate and the element substrate;
a sealing member which bonds the counter substrate and the element substrate to each other;
a plurality of pixel electrodes which are arranged on an effective pixel portion of the element substrate on which an image is displayed and have reflectivity;
a first conductive pattern which is formed by the same layer as the plurality of pixel electrodes and is provided between the effective pixel portion and the sealing member when seen from the above; and
a second conductive pattern which is formed by the same layer as the plurality of pixel electrodes and overlaps with the sealing member when seen from the above,
wherein the second conductive pattern has an area density per unit area, which is smaller than an area density of the first conductive pattern, when seen from the above.

2. The electrooptic device according to claim 1,
wherein the second conductive pattern includes a plurality of wirings which extend in the direction perpendicular to an extension direction of the sealing member when seen from the above.

3. The electrooptic device according to claim 2, further including a third conductive pattern which is connected to the second conductive pattern and is formed at an outer side of the sealing member.

4. The electrooptic device according to claim 3, further including a common electrode which is formed on a surface of the counter substrate, the surface being opposed to the element substrate, and to which a predetermined common voltage is applied,
wherein the common voltage is applied to the second conductive pattern through the third conductive pattern.

5. The electrooptic device according to claim 4,
wherein the second conductive pattern includes a connecting portion which electrically connects the plurality of wirings.

6. The electrooptic device according to claim 2,
wherein the pixel electrodes are provided so as to correspond to intersections of a plurality of scan lines and a plurality of data lines when seen from the above,
a pitch that the pixel electrodes are arranged is equal to an arrangement interval of the plurality of scan lines or the plurality of data lines, and
a pitch that the plurality of wirings are arranged is equal to the pitch that the pixel electrodes are arranged.

7. The electrooptic device according to claim 6,
wherein each width of the plurality of wirings is narrower than one side of each of the pixel electrodes when seen from the above.

8. The electrooptic device according to claim 2, further including a lower conductive pattern which is positioned at a side opposite to the counter substrate with respect to the pixel electrodes, the first conductive pattern, and the second conductive pattern,
wherein the second conductive pattern overlaps with the lower conductive pattern when seen from the above.

9. An electronic apparatus comprising the electrooptic device according to claim 1.
